(19) United States
(12) Patent Application Publication
(10) Pub. No.: US 2026/0017425 A1
(43) Pub. Date: Jan. 15, 2026

(54) INSIGHT TARGETING IN COMPUTER AIDED DESIGN AND MANUFACTURE

(71) Applicant: Autodesk, Inc., San Francisco, CA (US)

(72) Inventors: Ashish Arora, Toronto (CA); Ciaran Carroll, Toronto (CA); Ava Shoshtari, Vancouver (CA); Zhuoyu Peng, Lynnwood, WA (US)

(21) Appl. No.: 18/767,290

(22) Filed: Jul. 9, 2024

(51) Int. Cl. G06F 30/20

(52) U.S. Cl. CPC G06F 30/20

(57) ABSTRACT

Methods, systems, and apparatus, including medium-encoded computer program products, for insight targeting in computer aided design and manufacture, include: obtaining two or more suggested user interface actions, wherein each suggested user interface action of the two or more suggested user interface actions is proposed by an insight targeting model in response to a corresponding received user interface action with a three-dimensional modeling program; generating a score for each suggested user interface action of the two or more suggested user interface actions, wherein the score is based on a position of the suggested user interface action being received within a window that includes two or more user interface actions that are received after the corresponding received user interface action; and producing a performance evaluation result of the insight targeting model based on the scores for the two or more suggested user interface actions.

### BACKGROUND

This specification relates to computer aided design of physical structures to be manufactured using additive manufacturing, subtractive manufacturing and/or other manufacturing systems and techniques.

Computer Aided Design (CAD) software has been developed and used to generate three-dimensional (3D) representations of objects, and Computer Aided Manufacturing (CAM) software has been developed and used to manufacture the physical structure of those objects, e.g., using Computer Numerical Control (CNC) manufacturing techniques. The CAD software has also included software tools that can be used to redesign and enhance 3D parts of the objects. The CAD software has been used in conjunction with additive manufacturing systems and techniques and subtractive manufacturing systems and techniques.

However, users of a CAD or CAM software, particularly new users, may struggle to navigate through the complex software and may feel overwhelmed by the multitude of menus, options, and commands available. When encountering challenges or unfamiliar tasks, the users often need to search for help documentation online or rely on online communities, forums, and discussion boards. However, finding relevant and reliable information can be time-consuming and inefficient. Some users seek external training or enroll in courses to learn CAD or CAM skills. However, these resources are not personalized to the specific needs and context of individual users.

### SUMMARY

Insight targeting utilizes an insight targeting model to propose one or more most probable next user interface action (i.e., an insight) executed by a user in a three-dimensional (3D) modeling software given their current and/or preceding user interface actions. Insight targeting aims to improve product knowledge and optimize user interaction with the 3D modeling software by delivering the right insight at the right time.

This specification relates to a comprehensive and efficient way to assess the effectiveness of insights in driving desired user activities by considering the position of an insight in a sequence of user interface actions after an actual or intended exposure to an insight. Furthermore, the specification describes systems and techniques that automatically gather and summarize domain knowledge associated with an insight, providing users with concise and relevant summaries that are verified through prioritized and ranked questions based on a set of factors.

In general, one or more aspects of the subject matter described in this specification can be embodied in one or more methods (and also one or more non-transitory computer-readable mediums tangibly encoding a computer program operable to cause data processing apparatus to perform operations) including: obtaining two or more suggested user interface actions, wherein each suggested user interface action of the two or more suggested user interface actions is proposed by an insight targeting model in response to a corresponding received user interface action with a three-dimensional modeling program; generating a score for each suggested user interface action of the two or more suggested user interface actions, wherein the score is based on a position of the suggested user interface action being received within a window that includes two or more user interface actions that are received after the corresponding received user interface action; and producing a performance evaluation result of the insight targeting model based on the scores for the two or more suggested user interface actions.

The method (or operations performed by the data processing apparatus in accordance with the computer program tangibly encoded in one or more non-transitory computer-readable mediums) can include: receiving, by the three-dimensional modeling program, a current suggested user interface action that is proposed by the insight targeting model in response to a current received user interface action with the three-dimensional modeling program; determining, by the three-dimensional modeling program, whether to display the current suggested user interface action on a user interface of the three-dimensional modeling program based on the performance evaluation result of the insight targeting model; and in response to determining to display the current suggested user interface action, displaying, by the three-dimensional modeling program, the current suggested user interface action on the user interface of the three-dimensional modeling program.

The method (or operations performed by the data processing apparatus in accordance with the computer program tangibly encoded in one or more non-transitory computer-readable mediums) can include: generating, by a generative language model and based on domain knowledge data, text data associated with the current suggested user interface action; generating candidate questions based on the text data; calculating a mean and a standard deviation of respective scores for the candidate questions, wherein the score for each candidate question can include a weighted sum of a relevance score, a uniqueness score, a completeness score, an answerability score, a difficulty score, and a clarity score for the candidate question; selecting a subset of questions from the candidate questions by comparing the respective scores for the questions to a threshold determined based on the mean and the standard deviation; and determining whether to display the text data together with the current suggested user interface action by comparing (a) first answers to the subset of questions generated based on domain knowledge data, and (b) second answers to the subset of questions generated based on the text data.

The generating the score for each suggested user interface action can include: calculating a precision for the suggested user interface action, wherein the precision is a likelihood that the suggested user interface action is performed by a user within the window; calculating a positional decay weight using the position of the suggested user interface action being received within the window, wherein the positional decay weight is higher at a beginning of the window, in which the suggested user interface action occurs, than at an ending of the window; and calculating the score by multiplying the precision and the positional decay weight.

The generating the score for each suggested user interface action can include: determining two or more sub-windows of the window, wherein each sub-window of the two or more sub-windows includes a different subset of user interface actions from the two or more user interface actions that are received after the received user interface action; for each sub-window of the two or more sub-windows, determining a recall of the suggested user interface action within the sub-window, wherein the recall is a likelihood that the subset of user interface actions in the sub-window correspond to the suggested user interface action; and calculating the score by averaging the recalls for the two or more sub-windows. A size of the window is N, which is at least two, the two or more user interface actions within the window are at positions from 1 through N, determining the two or more sub-windows of the window can include: determining N sub-windows of the window, wherein each sub-window has a window length of n, and includes user interface actions at positions 1 through n of the window, n is between 1 and N.

The generating the score for each suggested user interface action can include: calculating a precision for the suggested user interface action, wherein the precision is a likelihood that the suggested user interface action is performed by a user within the window; calculating a positional decay weight using the position of the suggested user interface action being received within the window, wherein the positional decay weight is higher at a beginning of the window, in which the suggested user interface action occurs, than at an ending of the window; calculating a first score by multiplying the precision and the positional decay weight; determining two or more sub-windows of the window, wherein each sub-window of the two or more sub-windows includes a different subset of user interface actions from the two or more user interface actions that are received after the received user interface action; for each sub-window of the two or more sub-windows, determining a recall of the suggested user interface action within the sub-window, wherein the recall is a likelihood that the subset of user interface actions in the sub-window correspond to the suggested user interface action; calculating a second score by averaging the recalls for the two or more sub-windows; and generating the score based on the first score and the second score.

The performance evaluation result can include an average of the scores for the two or more suggested user interface actions. The method (or operations performed by the data processing apparatus in accordance with the computer program tangibly encoded in one or more non-transitory computer-readable mediums) can include: displaying, to a user and on a user interface of the three-dimensional modeling program, each suggested user interface action of the two or more suggested user interface actions after receiving the corresponding user interface action; and after displaying each suggested user interface action of the two or more suggested user interface actions to the user, receiving the two or more user interface actions performed by the user within the window.

One or more aspects of the subject matter described in this specification can also be embodied in one or more systems including: a non-transitory storage medium having instructions of a three-dimensional modeling program stored thereon; and one or more data processing apparatus configured to run the instructions of the three-dimensional modeling program to perform operations specified by the instructions of the three-dimensional modeling program; wherein the operations include: obtaining two or more suggested user interface actions, wherein each suggested user interface action of the two or more suggested user interface actions is proposed by an insight targeting model in response to a corresponding received user interface action with a three-dimensional modeling program; generating a score for each suggested user interface action of the two or more suggested user interface actions, wherein the score is based on a position of the suggested user interface action being received within a window that includes two or more user interface actions that are received after the corresponding received user interface action; and producing a performance evaluation result of the insight targeting model based on the scores for the two or more suggested user interface actions.

Particular embodiments of the subject matter described in this specification can be implemented to realize one or more of the following advantages.

The systems and techniques described improve the technical field of three-dimensional modeling and provide the technical effect of substantially reducing complexity of using computer-based tools by assisting the user in performing the technical task of three-dimensional modeling through insights and associated summaries. The systems and techniques described in this specification include a position-based metric for assessing the performance of an insight targeting model. The position-based metric modifies traditional precision and recall metrics by considering the execution position of an insight in a user interface action sequence window. This position-based metric helps determine how effectively the insights lead to the desired user actions and how promptly these actions are undertaken. For example, the systems and techniques introduce a position-weighted precision metric and an average recall metric by scoring accurate and timely insights higher the earlier the insights occur in a user interface action sequence window. The position-based metrics not only align with the objectives of insight targeting, but are also easy to interpret, thus ensuring their effectiveness even in situations where datasets might be imbalanced. For example, a position-based F-measure (e.g., a position-based F1 score) can provide a harmonic average of a position-based precision and a position-based recall, ensuring that imbalanced datasets do not adversely impact the interpretation of insight targeting performance. The position-based metrics have relatively low computational complexity, and thus they can also be utilized in real time monitoring use cases to ensure that the deployed insight targeting models are performing as desired and can detect model drifts.

The systems and techniques described in this specification include a metric for evaluating the factual consistency of document summarizations generated by a generative language model. Different from the existing Question Answering and Generation for Summarization (QAGS) method, the described Average Modified Question Answering and Generation for Summarization (AmQAGS) method uses a robust question ranking and thresholding logic based on a standardized and objective measure to ensure that only questions that satisfy a set of criteria are selected for the factual consistency analysis. The systems and techniques can apply the AmQAGS method to natural language summaries associated with an insight and can significantly reduce human intervention by automatically determining the quality and factual integrity of the natural language summaries, providing a safeguard against potential inaccuracies or misrepresentations in the generated summaries. Automating the evaluation of natural language summaries using the AmQAGS method can result in significant time and cost savings by reducing the need for manual intervention and review, and organizations can streamline their processes and allocate resources more efficiently. The AmQAGS method provides a standardized and objective measure for assessing the quality and accuracy of the natural language summaries. By relying on a defined metric rather than subjective human evaluation, the systems and techniques can ensure a more consistent and reliable evaluation process across all generated summaries. The AmQAGS method can be customized and adapted to different domains, industries, and use cases.

The details of one or more embodiments of the subject matter described in this specification are set forth in the accompanying drawings and the description below. Other features, aspects, and advantages of the invention will become apparent from the description, the drawings, and the claims.

### BRIEF DESCRIPTION OF THE DRAWINGS

FIG. 1 shows an example of a system usable to perform insight targeting in computer aided design and manufacturing.

FIG. 2 is an example of a user interface action sequence and insights.

FIG. 3 is a flowchart showing an example of a process to evaluate an insight targeting model.

FIG. 4A is a flowchart showing an example of a process to calculate a position-weighted precision.

FIG. 4B is an example of positional decay weightings.

FIG. 5A is a flowchart showing an example of a process to calculate an average recall.

FIG. 5B is an example of a look-up table for average recalls at various adoption positions.

FIG. 5C is an example of calculating an average recall.

FIG. 6 is a flowchart showing an example of a process to calculate a position-based F-measure.

FIG. 7 is a flowchart showing an example of a process to generate a summary associated with an insight.

FIG. 8 is a schematic diagram of a data processing system including a data processing apparatus, which can be programmed as a client or as a server.

Like reference numbers and designations in the various drawings indicate like elements.

### DETAILED DESCRIPTION

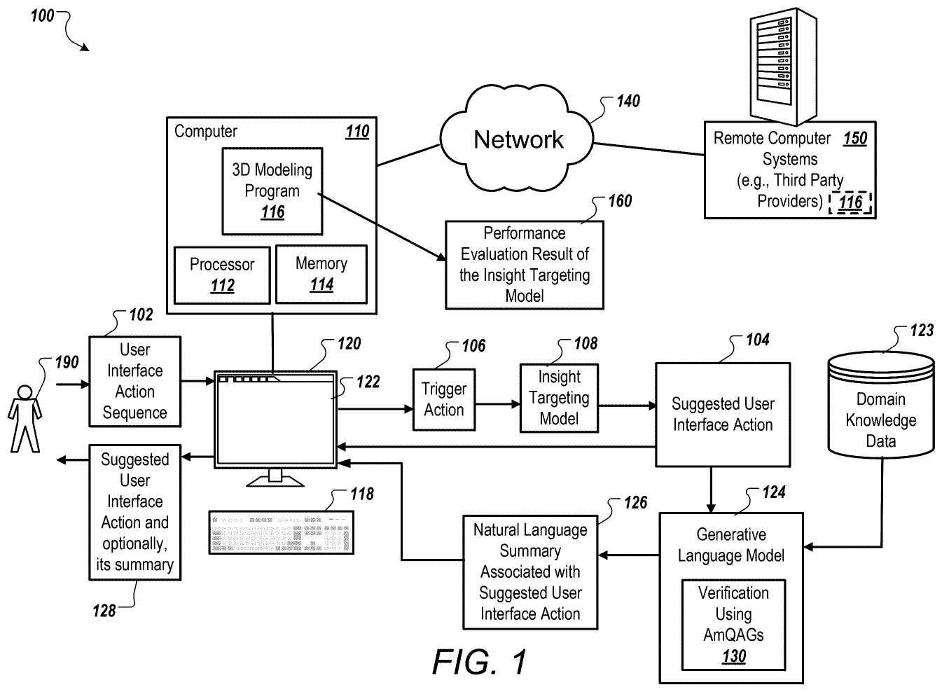

FIG. 1 shows an example of a system 100 usable to perform insight targeting in computer aided design and manufacturing. A computer 110 includes a processor 112 and a memory 114, and the computer 110 can be connected to a network 140, which can be a private network, a public network, a virtual private network, etc. The processor 112 can be one or more hardware processors, which can each include multiple processor cores. The processor 112 can include central processing units (CPUs) and graphics processing units (GPUs) that are used to process data using a machine learning model. The memory 114 can include both volatile and non-volatile memory, such as Random Access Memory (RAM) and Flash RAM. The computer 110 can include various types of computer storage media and devices, which can include the memory 114, to store instructions of programs that run on the processor 112, including a three-dimensional (3D) modeling program 116.

The 3D modeling program 116 can run locally on computer 110, remotely on a computer of one or more remote computer systems 150 (e.g., one or more third party providers' one or more server systems accessible by the computer 110 via the network 140) or both locally and remotely. Thus, the 3D modeling program 116 can be two or more programs that operate cooperatively on two or more separate computer processors in that a program operating locally at computer 110 can offload processing operations “to the cloud” by having one or more programs on one or more remote computer systems 150 perform the offloaded processing operations.

The 3D modeling program 116 presents a user interface (UI) 122 on a display device 120 of the computer 110, which can be operated using one or more input/output devices 118 of the computer 110 (e.g., keyboard and mouse). Note that while shown as separate devices in FIG. 1, the display device 120 and/or input/output devices 118 can also be integrated with each other and/or with the computer 110, such as in a tablet computer (e.g., a touch screen can be an input/output device 118, 120). Moreover, the computer 110 can include or be part of a virtual reality (VR) or augmented reality (AR) system. For example, the input/output devices 118, 120 can include a VR/AR input glove and/or a VR/AR headset.

The 3D modeling program 116 can be Computer Aided Design (CAD) program(s). As used herein, CAD program(s) refers to any suitable program used to design physical structures that meet specified design requirements, regardless of whether or not the program is capable of interfacing with and/or controlling specific manufacturing equipment. Thus, 3D modeling program 116 can include Computer Aided Industrial Design (CAID) program(s), Computer Aided Engineering (CAE) program(s), Computer Aided Manufacturing (CAM) program(s), etc. In some implementations, the 3D modeling program 116 can be computer programs for computer animation, such as graphics programs, collision detection programs, and rendering programs for display of scenes. In some implementations, the systems and techniques described in this application are used in a computer program with a user interface that provides functions beyond 3D modeling. For example, the systems and techniques described here in can be used in two-dimensional (2D) design, 2D modeling, 2D graphic editing, and computer animation programs and applications.

However, users of the 3D modeling program 116, particularly new users, may face challenges to navigate through the software and to find relevant and reliable information when encountering unfamiliar tasks. The users often rely on self-exploration, manual search, external training, or community support to address the challenges. While these methods may provide some level of assistance, these methods are often time-consuming, lacking personalization, and require users to actively seek out information.

The 3D modeling program 116 performs insight targeting using an insight targeting model 108. Insight targeting aims to automate and streamline user interaction with the CAD program(s) by leveraging predictive algorithms and summarizing online help documentation, providing personalized and timely guidance to CAD users. Insight targeting utilizes the insight targeting model 108 to propose a suggested user interface action 104 (i.e., an insight) with the 3D modeling program 116 given a user's current and/or preceding user interface actions, e.g., a trigger action 106, with the 3D modeling program 116.

The 3D modeling program 116 receives user interface action sequence 102 executed by a user 190 and the sequence 102 includes a sequence of user interface actions with the UI 122 of the 3D modeling program 116. For example, the user interface action sequence 102 can include a sequence of the following actions: “create new document”, “visibility toggle”, “create sketch”, “add polynomial line”, “drag sketch”, and “add sketch dimension”.

The 3D modeling program 116 implements an insight targeting model 108 that proposes at least one suggested user interface action 104 in response to a corresponding received user interface action, e.g., a trigger action 106. For example, after receiving the user interface action “create new document”, the insight targeting model 108 can propose a suggested user interface action “create a sketch” which is a probable next user interface action to be executed by the user 190 in the 3D modeling program 116 given the “create new document” user interface action.

In some implementations, the insight targeting model 108 can generate personalized guidance tailored to the individual needs and context of each CAD user. This personalized approach ensures that the users can receive recommendations and directions that are relevant to their specific tasks and workflows. For example, the 3D modeling program 116 can provide as an input to the insight targeting model a prompt that describes the current task of a CAD user and prior user interface actions with the 3D modeling program. Based on the prompt, the insight targeting model 108 can generate a personalized suggested next user interface action tailored to the CAD user's current task. In some implementations, the 3D modeling program 116 can provide as an input to the insight targeting model additional information about the CAD user, such as demographics information about the CAD user, and the insight targeting model can generate an appropriate suggested user interface action based on the additional information about the CAD user. For example, the 3D modeling program 116 can provide user experience level of a CAD user as an input to the insight targeting model, and the insight targeting model can generate a suggested user interface action with an appropriate level of detail, voice, or tone.

Examples of the insight targeting model 108 include a rule-based model, a Markov chain that utilizes historic usage patterns of the software, a generative language model, e.g., a large language model (LLM), trained to predict a user's next user interface action given their preceding one or more user interface actions. In some implementations, the insight targeting model 108 can include a rule-based model that operates through a set of rules that are developed using one or more users' historic usage data indicating usage patterns of the 3D modeling program 116. The set of rules can include a set of conditions determined based on the expectations and assumptions of an expert in 3D modeling regarding typical user behaviors. These conditions, including primary triggers, secondary triggers, stop conditions, and vocabulary, can collaboratively define the insight triggering criteria for each insight identified by the expert. For example, the 3D modeling program 116 can process user interface actions in the sequence 102. Based on detecting a trigger action 106, the 3D modeling program 116 can generate the suggested user interface action 104 based on the rules defined in a rule-based insight targeting model.

In some implementations, the insight targeting model 108 can include a Markov chain that utilizes historic usage patterns of the users of the 3D modeling program 116 to identify the most probable next user interface action executed by a user given their current and preceding user interface actions. Historical usage patterns can be aggregated and translated to probabilities in a transition matrix. The values within the cells of the transition matrix can represent a probability that a next user interface action is executed by a user immediately after an input user interface action, given the input user interface action. For a number of recent user interface actions, the 3D modeling program 116 can search the transition matrix to identify user interface actions that have the highest probabilities, and based on the identified user interface actions, the 3D modeling program 116 can generate a suggested user interface action 104.

In some implementations, the insight targeting model 108 can include a generative language model to predict users' next actions given their preceding activity. The generative language model, e.g., a large language model (LLM), can be trained (e.g., fine-tuned) using historical user interface action data. The 3D modeling program 116 can provide the user interface action sequence 102 as input to the generative language model to generate a generative output. The generative output can be parsed to identify most probable next user interface actions.

Execution of a suggested user interface action may not immediately follow the proposal of an insight; users may execute unrelated user interface actions prior to adoption of the insight. Immediate execution and delayed execution of a suggested action can indicate different performance of the insight targeting model. In some cases, a “Create a Sketch” insight can be adopted by a user immediately after the user's execution of a “New Document” user interface action. In some cases, a user may execute one or two other user interface actions before a user interface action associated with an insight is executed. For example, the user may execute a “Visibility toggle” user interface action followed by the “Sketch create” user interface action. The user's execution of the “Sketch create” user interface action immediately or soon after the trigger action indicates that the prior “Create a Sketch” insight was appropriate. But if the user does not adopt the insight or adopts the insight after executing too many unrelated user interface actions, the prior “Create a Sketch” insight was not appropriate, or at least not as appropriate as it could have been.

Given the diverse insight targeting approaches outlined above, it is desirable to have a method to quantitatively evaluate which approach performs best in triggering the right insight at the right time. Whether and when a suggested user interface action is executed by a user can characterize the performance of the insight targeting model. Some performance metrics, such as precision and recall, relate to the accuracy of predictions made by a predictive model. Precision measures the accuracy of positive predictions, while recall measures the completeness of positive predictions. High precision and high recall are desirable, but there may be a trade-off between the two metrics in some cases. An F-measure is a measure of predictive performance. For example, an F-score is an example of the F-measure and is the harmonic mean of a system's precision value and recall value. However, these traditional performance metrics do not consider the position of the suggested user interface action in a window of actions received after the trigger action. The specification describes a position-based metric that implements a window of a predetermined length that includes two or more user interface actions received after a user interface trigger action to identify whether an insight (i.e., a suggested user interface action) was appropriate at the time the insight targeting model proposes the insight.

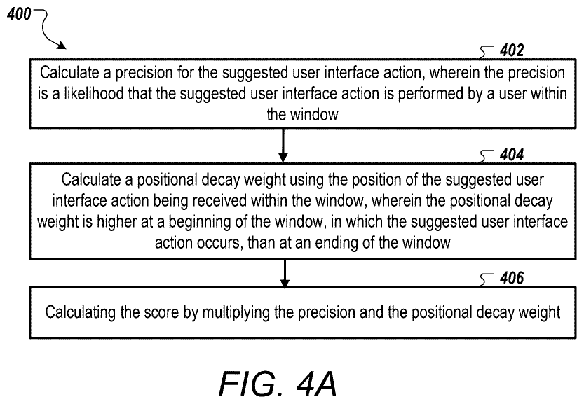

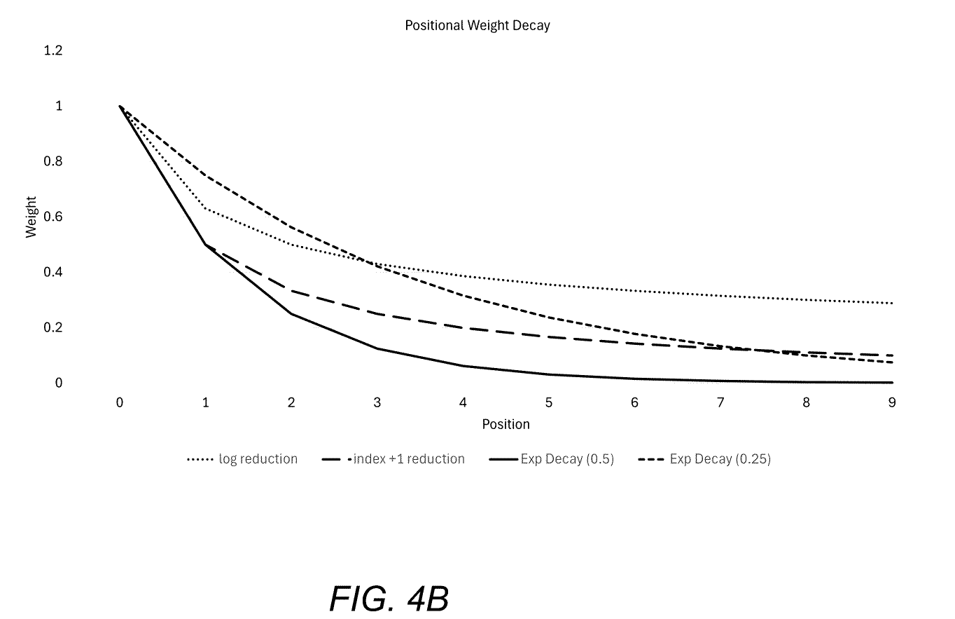

Using the position-based metric, the 3D modeling program 116 generates a score for a suggested user interface action 104 based on the position of the suggested user interface action 104 within a window that includes a predetermined number of user interface actions that are received after a trigger action 106. The number of user interface actions in the window is the length of the window. The length of the window can be determined based on whether the position-based metric is being used to evaluate an immediate or a longer term impact of the insights. For example, a small window length (e.g., 2, 3, or 4) can be chosen when the position-based metric is being used to evaluate an immediate impact of the insights. A large window length (e.g., 7, 10, or 15) can be chosen when the position-based metric is being used to evaluate a longer term impact of the insights. The position-based metric can generate a higher score when the suggested user interface action is executed immediately after the trigger action than when the suggested user interface action is executed later after the trigger action. The 3D modeling program 116 uses the position-based metric to generate a performance evaluation result 160 of the insight targeting model 108. More details of the position-based metric are described later in connection with FIGS. 4A and 4B, FIGS. 5A, 5B, and 5C, and FIG. 6.

For example, the window can be an action sequence window with a predetermined length N, that includes N user interface actions that are received after the trigger action 106. The 3D modeling program 116 determines whether the suggested user interface action 104 is received within the window. If the suggested user interface action 104 is received within the window, the 3D modeling program 116 determines a position of the suggested user interface action 104 within the window and can generate a score for the suggested user interface action 104 based on the position. If the suggested user interface action 104 is not received within the window, the 3D modeling program 116 determines that the suggested user interface action 104 is not adopted by the user 190 and can generate a score for the suggested user interface action 104 characterizing that the suggested user interface action 104 is not adopted by the user 190, e.g., a score of 0.

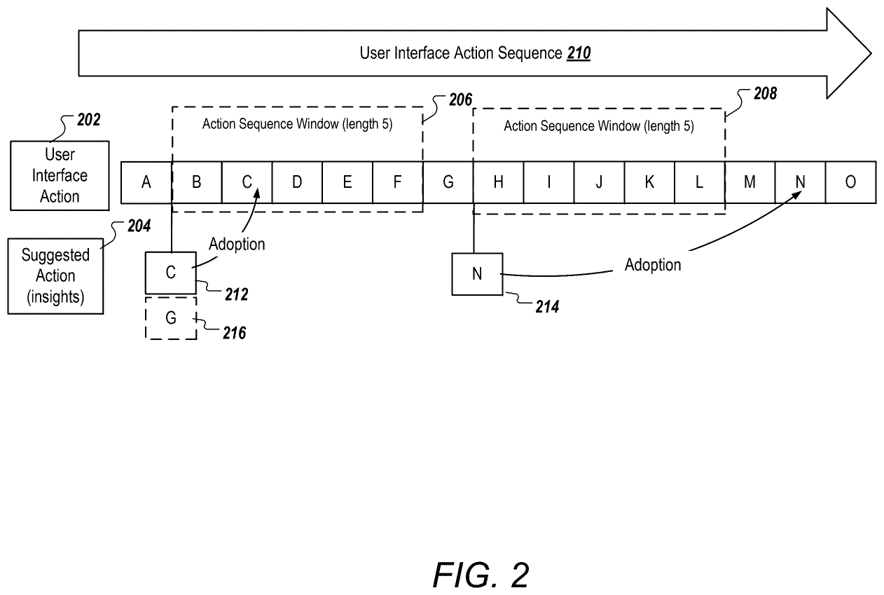

FIG. 2 is an example of a user interface action sequence 210 and corresponding insights 204. The user interface action sequence 210 includes user interface actions 202: A, B, C, D, E, F, . . . , O. An insight targeting model proposes a suggested user interface action 204 in response to a trigger action. For example, in response to the user interface action A, the insight targeting model proposes a suggested user interface action C 212. In response to the user interface action G, the insight targeting model proposes a suggested user interface action N 214.

The 3D modeling program 116 determines a window that includes a predetermined number of user interface actions that are received after a trigger action 106. For example, the window 206 is an action sequence window with a predetermined length of five, and includes user interface actions B, C, D, E, and F that are received after the trigger action A. Similarly, the window 208 is an action sequence window with a predetermined length of five, and includes user interface actions H, I, J, K, and L that are received after the trigger action G. Each action in the window is located at a position in the window. For example, action B is at the first position of the window 206, and action C is at the second position of the window 206, and so on.

The 3D modeling program 116 determines whether the suggested user interface action 104 is received within the window. If the suggested user interface action 104 is received within the window, the 3D modeling program 116 determines a position of the suggested user interface action 104 within the window. For example, the suggested user interface action C is received at the second position of the window 206, and the suggested user interface action N is received outside the window 208.

The 3D modeling program 116 can generate a score for the suggested user interface action based on its position within the window. For example, the 3D modeling program 116 can generate a position-weighted precision for the action C by multiplying a precision for the action C and a positional decay weight. The positional decay weight is higher at the beginning of the window, in which the suggested user interface action occurs, than at the ending of the window. Because the suggested user interface action N is received outside the window 208, the position-weighted precision for the action N is zero.

Referring back to FIG. 1, the 3D modeling program 116 can obtain two or more suggested user interface actions 104 and each suggested user interface action of the two or more suggested user interface actions is proposed by the insight targeting model 108 in response to a corresponding received user interface action (e.g., a corresponding trigger action 106) with the 3D modeling program 116. After generating a score for each suggested user interface action of the two or more suggested user interface actions, the 3D modeling program 116 can produce a performance evaluation result 160 of the insight targeting model 108 based on the scores for the two or more suggested user interface actions. For example, the performance evaluation result 160 of the insight targeting model 108 can be an average or a median of the scores for the two or more suggested user interface actions.

In some implementations, the 3D modeling program 116 can display to the user 190 and on the UI 122 of the 3D modeling program 116, the suggested user interface action 104 after receiving the corresponding user interface trigger action 106. That is, the 3D modeling program 116 can expose the suggested user interface action 104 to the user 190 and can determine the performance evaluation result 160 of the insight targeting model 108 based on whether and when the suggested user interface action 104 is adopted by the user 190 in response to exposure to the insight. In some implementations, the 3D modeling program 116 may not display the suggested user interface action 104 to the user 190 and can determine the performance evaluation result 160 of the insight targeting model 108 based on whether and when the suggested user interface action 104 is executed by the user 190.

The 3D modeling program 116 can use the position-based metric to evaluate and compare the performances of two or more insight targeting approaches by back-testing against historical usage data and identifying which approach predicts user interface actions most effectively. For example, the 3D modeling program 116 can compute and compare respective performance evaluation results 160 for a rule-based insight targeting model, a Markov chain insight targeting model, and a generative language insight targeting model. The 3D modeling program 116 can select the insight targeting model with the best performance evaluate result and can use the selected insight targeting model in the system 100.

Because the position-based metrics have relatively low computational complexity, in some implementations, the 3D modeling program 116 can use the position-based metrics in real time monitoring use-cases to ensure that a deployed insight targeting model is performing as desired and can issue a warning when the insight targeting model drifts from a desired performance. For example, the 3D modeling program 116 can receive a current suggested user interface action that is proposed by the insight targeting model in response to a current received user interface action with the 3D modeling program 116. The 3D modeling program 116 can determine whether to display the current suggested user interface action on a user interface of the 3D modeling program based on the performance evaluation result of the insight targeting model. For example, the 3D modeling program 116 can determine whether the average of the scores for the two or more previously suggested user interface actions is larger than a threshold. If the average score is larger than the threshold, the 3D modeling program 116 can determine to display the current suggested user interface action on a user interface of the 3D modeling program. If the average score is not larger than the threshold, the 3D modeling program 116 can determine not to display the current suggested user interface action on the user interface of the 3D modeling program.

In some implementations, for example, during a simulation of insight targeting, the insight targeting model can generate multiple suggested user interface actions 104 simultaneously in response to a trigger action 106. The 3D modeling program 116 can determine the effectiveness of the multiple simultaneously suggested insights using the scores for the multiple suggested insights under the position-based metric. Because displaying multiple insights to a user simultaneously can result in information overload or insight toxicity, in some implementations, the 3D modeling program 116 can penalize displaying multiple insights to users. For example, a penalty for simultaneously suggested insights can be introduced by adding a penalty term to the position-based metric calculation. For example, the 3D modeling program 116 can penalize displaying multiple simultaneously suggested insights by multiplying a position-weighted precision or an average recall by a number that equals one over the number of simultaneously suggested insights. In some implementations, the 3D modeling program 116 can select one insight from the multiple suggested user interface actions based on scores for previous similar insights and can display the selected insight.

For example, referring to FIG. 2, the insight targeting model can generate two suggested user interface actions C 212 and G 216 in response to the trigger action A in the sequence 210. A user immediately executes an action associated with the suggested user interface action C 212. However, the adoption of the suggested user interface action G 216 occurs significantly later in the sequence 210 outside the window 206. The 3D modeling program 116 can determine the effectiveness of the insights C 212 and G 216 using the scores for the insights C 212 and G 216 under the position-based metric. For example, the score for the insight C 212 can be 0.26 and the score for the insight G216 can be zero, indicating that the insight C212 is appropriate and the insight G216 is not appropriate (or not as appropriate).

Referring to FIG. 1, in some implementations, the 3D modeling program 116 can automatically gather and summarize domain knowledge, providing users with concise and relevant information that can help users to efficiently navigate and use the 3D modeling program. In some implementations, after obtaining the suggested user interface action 104, the 3D modeling program 116 can generate, using a generative language model 124 and based on domain knowledge data 123, a natural language summary 126 associated with the suggested user interface action 104. The 3D modeling program can display to the user 190 the natural language summary 126 together with the suggested user interface action 104 on the UI 122 of the computer 110. For example, after receiving a trigger action 106, the 3D modeling program 116 can display a pop-up window showing the suggested user interface action, and optionally the associated summary 128. By presenting guidance in a user-friendly manner, new CAD users can more easily understand and follow the suggested user interface actions, promoting a smoother learning process.

The domain knowledge data 123 can be stored in a database installed on the computer 110, the remote computer 150, or another computer. The domain knowledge data 123 can include help documentation, user manuals, domain expert knowledge data, and other data from online communities, forums, and discussion boards in the domain of 3D modeling, e.g., in the domain of CAD.

The generative language model 124 can process and extract information associated with the suggested user interface action 104 from various sources in the domain knowledge data 123. Thus, the users of the 3D modeling program do not need to search through extensive documentation and online resources themselves. Rather than presenting technical jargons and complex instructions, the generative language model 124 can provide the summary of information in natural language, which is easier for the users to follow along. For example, a natural language summary 126 associated with a suggested user interface action 104 can include an explanation of the suggested user interface action 104, a figure showing where to find the user interface action in the menu, some example results of executing the action, a link to documentation and online discussions related to the action, or a combination of these.

In some implementations, the 3D modeling program 116 performs a verification 130 of the natural language summary 126 before displaying the summary 126 to the user 190 on the UI 122. Some existing verification methods verify the summaries by cross-checking against the domain knowledge data and the summary itself through questioning and answering. For example, the Question Answering and Generation for Summarization (QAGS) method includes the following steps: generating questions based on the summary, generating answers for each question based on both the summary and the original text in the domain knowledge data, determining a performance score for the summary as a ratio of the number of matching answers to the total number of questions. However, some of the generated questions may not have high quality and may not be relevant to the summary, thus affecting the effectiveness of the verification of the summaries.

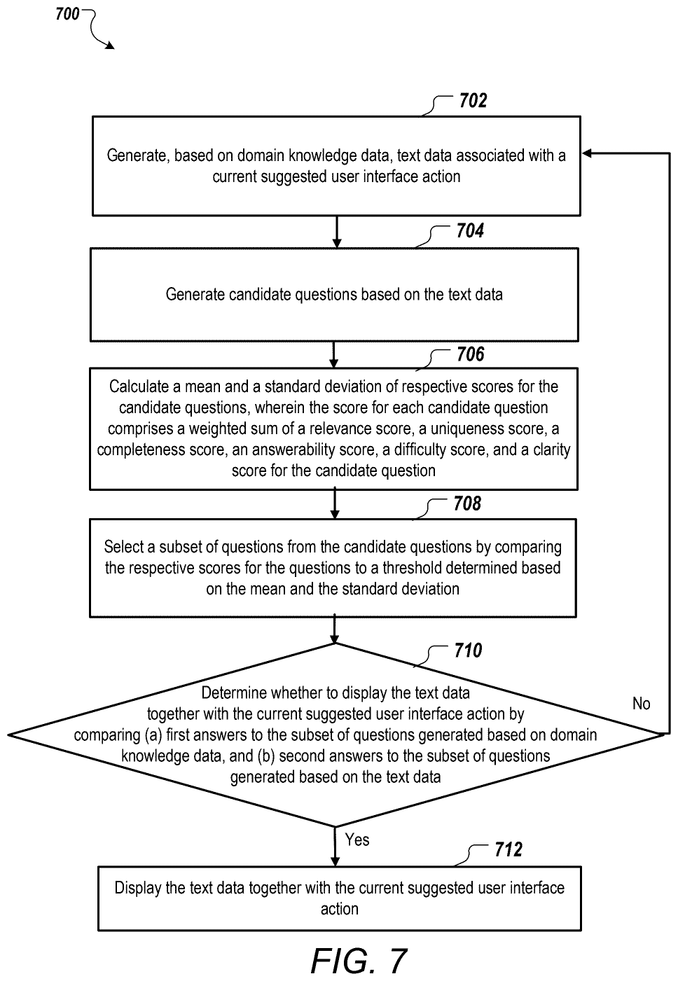

Rather than using the existing QAGS method, the 3D modeling program 116 performing the verification 130 can use the Average Modified Question Answering and Generation for Summarization (AmQAGS) method. Different from the existing QAGS method, the AmQAGS method uses a robust question ranking and thresholding logic to ensure that only high-quality and relevant questions are selected for the factual consistency analysis. The 3D modeling program 116 can apply the AmQAGS method to natural language summaries associated with an insight and can significantly reduce human intervention by automatically determining the quality and factual integrity of the natural language summaries, providing a safeguard against potential inaccuracies or misrepresentations in the generated summaries. More details of the AmQAGS method are described in connection with FIG. 7.

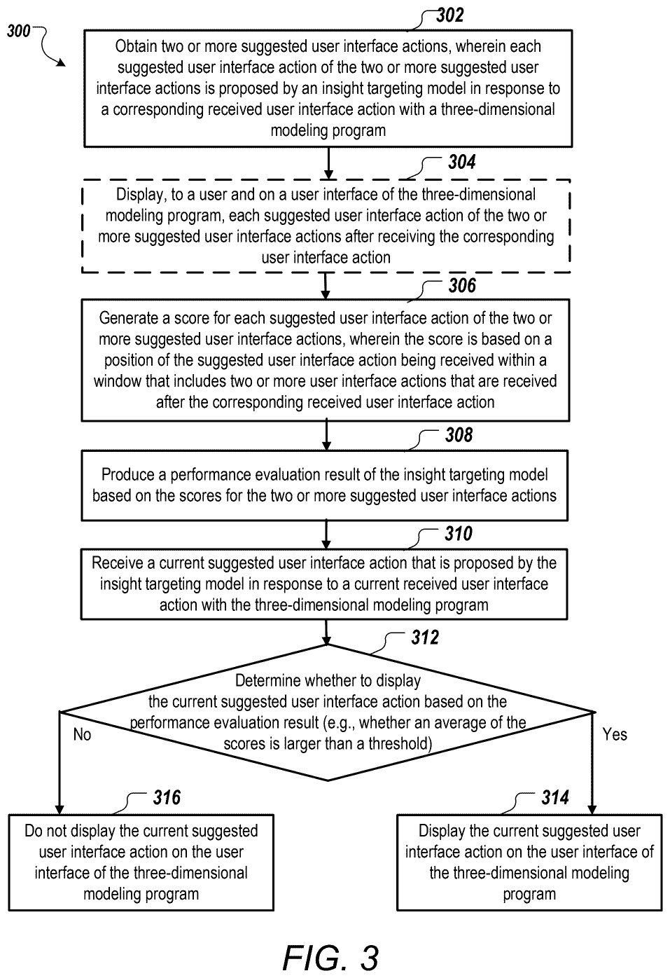

FIG. 3 is a flowchart showing an example of a process 300 to evaluate an insight targeting model. Two or more suggested user interface actions are obtained 302, e.g., by the 3D modeling program 116. Each suggested user interface action of the two or more suggested user interface actions can be proposed by an insight targeting model in response to a corresponding received user interface action with the 3D modeling program. In some implementations, the two or more suggested user interface actions and the corresponding received user interface actions can be from multiple sessions of using a CAD software, from multiple users, from different times and dates, or a combination of these. In some implementations, after receiving the corresponding user interface action, each suggested user interface action of the two or more suggested user interface actions can be displayed 304 to a user and on a user interface of the 3D modeling program, e.g., by the 3D modeling program 116.

A score for each suggested user interface action of the two or more suggested user interface actions is generated 306, e.g., by the 3D modeling program 116. The score is based on a position of the suggested user interface action being received within a window that includes two or more user interface actions that are received after the corresponding received user interface action. In some implementations, after displaying each suggested user interface action of the two or more suggested user interface actions to the user, the 3D modeling program 116 can receive the two or more user interface actions performed by the user within the window in response to the user observing the two or more suggested user interface actions.

A performance evaluation result of the insight targeting model is produced 308 based on the scores for the two or more suggested user interface actions, e.g., by the 3D modeling program 116. In some implementations, the performance evaluation result can include an average of the scores for the two or more suggested user interface actions. For example, the performance evaluation result can be an average of the scores for multiple suggested user interface actions among sessions, users, times and/or dates.

In some implementations, a current suggested user interface action that is proposed by the insight targeting model in response to a current received user interface action with the 3D modeling program can be received 310, e.g., by the 3D modeling program 116. In some implementations, whether to display the current suggested user interface action on a user interface of the 3D modeling program can be determined 312 based on the performance evaluation result of the insight targeting model, e.g., by the 3D modeling program 116. In some implementations, in response to determining to display the current suggested user interface action, the current suggested user interface action can be displayed 314 on the user interface of the 3D modeling program, e.g., by the 3D modeling program 116. In some implementations, in response to determining not to display the current suggested user interface action, the current suggested user interface action will not be displayed 316 on the user interface of the 3D modeling program.

In some implementations, the 3D modeling program 116 can check repetitiveness (e.g., prior exposure to the insight), redundancy (e.g., prior user interface action associated with the insight) of the current suggested user interface action, and the 3D modeling program 116 can display the current suggested user interface action to the user when the repetitive and redundant checks pass. For example, if the 3D modeling program 116 has recently displayed the same current suggested user interface action to the user, the 3D modeling program 116 can determine not to display the current suggested user interface action to the user because of repetitiveness. As another example, if the user recently has executed a user interface action associated with the current suggested user interface action, the 3D modeling program 116 can determine not to display the current suggested user interface action to the user because of redundancy.

In some implementations, generating 306 the score for each suggested user interface action can include generating a position-weighted precision. FIG. 4A is a flowchart showing an example of a process 400 to calculate a position-weighted precision. A precision for the suggested user interface action can be calculated 402, e.g., by the 3D modeling program 116. The precision is a likelihood that the suggested user interface action is performed by a user within the window that includes user interface actions executed by the user after the trigger action. For example, the precision can be calculated as TP/(TP+FP), in which TP is the true positive and FP is the false positive. For example, if there is only one suggested user interface action in response to a trigger action and the suggested user interface action is executed by the user anywhere within the window, the true positive value is 1 (TP=1). Because there are no other insights in response to the trigger action, there are no false positives (FP=0). Thus, the precision is calculated as TP/(TP+FP)=1. As another example, if there are two suggested user interface actions in response to a trigger action and only one of the two suggested user interface actions is executed by the user anywhere within the window, the true positive value is 1 (TP=1) and the false positive is 1 (FP=1). Thus, the precision is calculated as TP/(TP+FP)=1/2.

In some implementations, there can be multiple occurrences of an insight in a window. For example, a “Sketch create” user interface action associated with an insight “Create a Sketch” can be executed twice within a window of a length of five. The precision is TP/(TP+FP)=2/(2+0)=1. In some implementations, there can be no occurrence of an insight in a window. The precision is TP/(TP+FP)=0/(0+0)=NA.

A positional decay weight can be calculated 404 using the position of the suggested user interface action being received within the window, e.g., by the 3D modeling program 116. The positional decay weight is higher at the beginning of the window, in which the suggested user interface action occurs, than at the ending of the window. In some implementations, the precision decay weight can follow a log reduction, e.g.,

$$\frac{1}{{log}_{2} i + 2} ,$$

an index+1 reduction, e.g.,

$$\frac{1}{i + 1} ,$$

an exponential decay, e.g., (1−rate)ⁱ, or any other suitable decay formula. Here, i is the position of the suggested user interface action being received within the window following a zero-based index. The rate is the decay rate in an exponential decay and the decay rate can be a number between 0 and 1. FIG. 4B is an example of positional decay weightings following a log reduction, an index+1 reduction, an exponential decay with rate equals 0.5, and an exponential decay with rate equals 0.25.

The score (i.e., a position-weighted precision) can be calculated 406 by multiplying the precision and the positional decay weight, e.g., by the 3D modeling program 116. For example, in FIG. 2, the precision for the suggested user interface action C 212 is 1. The suggested user interface action C 212 is adopted at the second position in the window (i=1). The positional decay weight under an exponential decay with a decay rate of 0.5 is (1-0.5)=0.5. Therefore, the position-weighted precision for the suggested user interface action C 212 is 0.5.

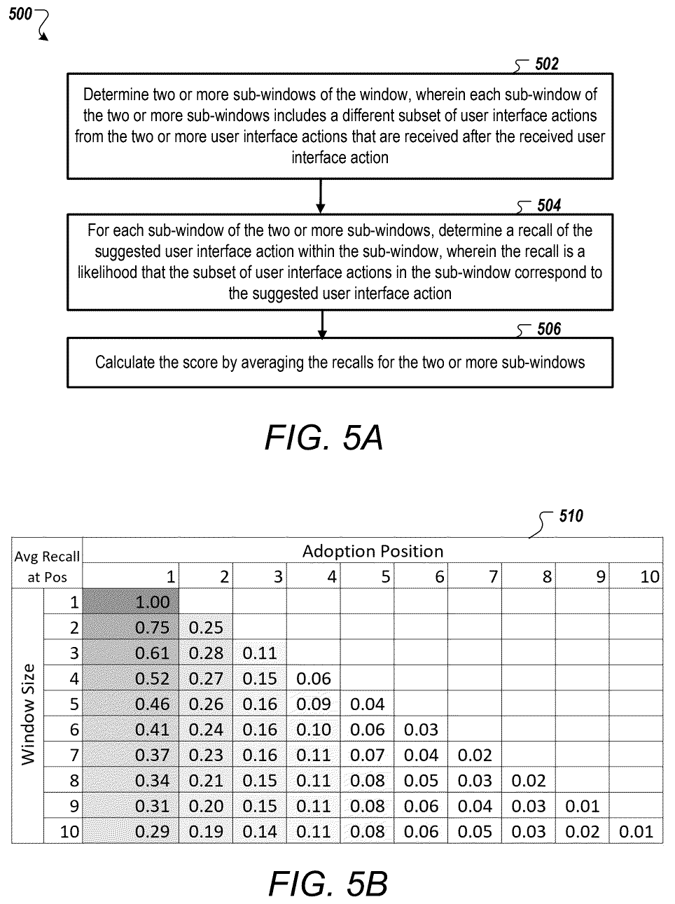

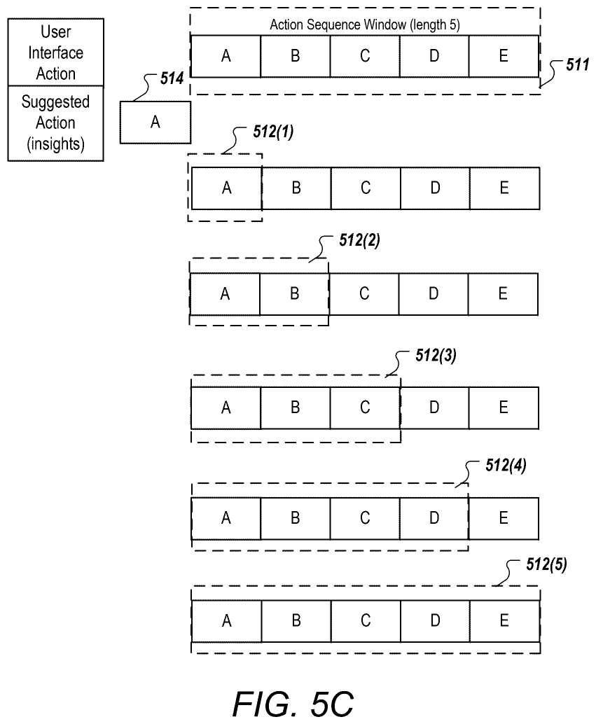

In some implementations, generating 306 the score for each suggested user interface action can include generating an average recall. FIG. 5A is a flowchart showing an example of a process 500 to calculate an average recall. Two or more sub-windows of the window can be determined 502, e.g., by the 3D modeling program 116. Each sub-window of the two or more sub-windows includes a different subset of user interface actions from the two or more user interface actions that are received after the received user interface action. For example, the size of the window can be N, which is at least two, and the two or more user interface actions within the window can be at positions from 1 through N. In some implementations, determining 502 the two or more sub-windows of the window can include determining N sub-windows of the window, and each sub-window can have a window length of n, and can include user interface actions at positions 1 through n of the window, and n is between 1 and N.

For each sub-window of the two or more sub-windows, a recall of the suggested user interface action within the sub-window can be determined 504, e.g., by the 3D modeling program 116. The recall is a likelihood that the subset of user interface actions in the sub-window correspond to the suggested user interface action. The score (i.e., an average recall) can be calculated 506 by averaging the recalls for the two or more sub-windows, e.g., by the 3D modeling program 116.

The recall can be calculated as TP/(TP+FN), in which TP is the true positive and FN is the false negative. For example, a window with a length of five can include a maximum of 5 potential insight opportunities. If there is one suggested user interface action in response to a trigger action and the suggested user interface action is executed once within the window of a length of five, the true positive value is 1 (TP=1). Four user interface actions are left unpredicted, and so the false negative is 4 (FN=4). Tus, the recall is calculated as TP/(TP+FN)=1/5. In some implementations, there can be multiple occurrences of an insight in a window. For example, a “Sketch create” user interface action associated with an insight “Create a Sketch” can be executed twice within a window of a length of five. The recall is TP/(TP+FN)=2/(2+3)=2/5. In some implementations, there can be no occurrence of an insight in a window. The recall is TP/(TP+FN)=0/(5)=0.

FIG. 5C is an example of calculating an average recall. For an action sequence window 511 with a length of five, there are five sub-windows 512(1), 512(2), 512(3), 512(4), and 512(5). All sub-windows start at the first position in the window 511. The first sub-window 512(1) includes the user interface action A at the 1^{st} position in the window 511. The second sub-window 512(2) includes the user interface action A at the 1^{st} position and the action B at the 2^{nd} position in the window 511. Similarly, the third sub-window 512(3) includes the user interface actions A, B, and C. The fourth sub-window 512(4) includes the user interface actions A, B, C, and D. The fifth sub-window 512(5) includes the user interface actions A through E (but still referred to as a sub-window even though it includes all user interface actions found in the window 511).

A suggested user interface action A 514 is adopted at the 1^{st} position in the window 511. For each sub-window of the two or more sub-windows, the 3D modeling program 116 calculates a recall of the suggested user interface action A 514. For example, for the first sub-window 512(1), the recall is 1. For the second sub-window 512(2), true positive is 1 and false negative is 1 because B is not a proposed insight. The recall is TP/(TP+FN)=1/(1+1)=0.5. Similarly, the recall for the sub-windows 512(3), 512(4), and 512(5) are 0.33, 0.25, and 0.2, respectively. Finally, an average recall can be calculated by averaging the recalls for the five sub-windows and the average recall in this example is (1+0.5+0.33+0.25+0.2)/5=0.46.

In some implementations, the 3D modeling program 116 can determine the average recall for a suggested user interface action using a look-up table, saving the computation time and computation resources at run time. The look-up table can include precomputed average recall for various window sizes and for various adoption positions. The 3D modeling program 116 can determine the average recall for a suggested user interface action by indexing the look-up table using a window size of the user interface actions sequence window and the adoption position of the suggested user interface action.

FIG. 5B is an example of a look-up table 510 for average recalls at various adoption positions. The look-up table 510 shows that immediate adoptions can score higher than delayed adoptions, and larger window sizes can increase adoption opportunities but can decrease the average recall scores. The suggested user interface action 514 in FIG. 5C is adopted at an adoption position 1 in a window of a size of five. By indexing the fifth row and the first column of the look-up table 510 in FIG. 5B, the 3D modeling program 116 can determine that the average recall is 0.46. The look-up table in FIG. 5B assumes only one suggested user interface action is generated for a trigger action and the suggested user interface action is executed or adopted only once within the window. Similar look-up tables can be computed for situations with two or more suggested user interface actions and/or two or more executions or adoptions of a suggested user interface action.

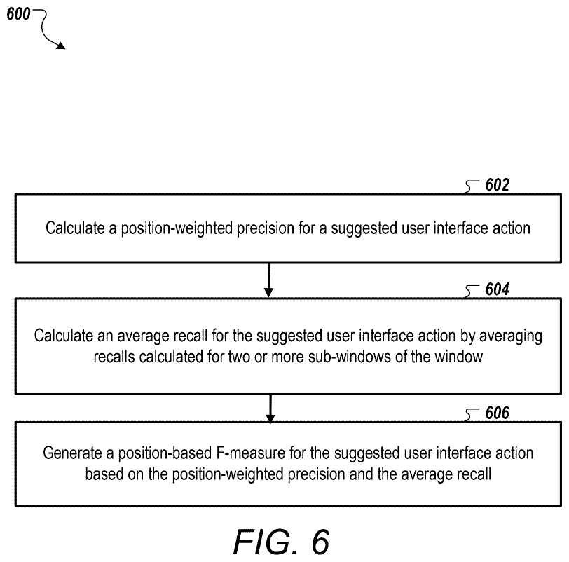

In some implementations, generating 306 the score for each suggested user interface action can include generating a position-based F-measure. An F-measure is a measure of predictive performance. For example, an F-score is an example of the F-measure and is the harmonic mean of a system's precision value and recall value. FIG. 6 is a flowchart showing an example of a process 600 to calculate a position-based F-measure, which is the harmonic mean of a position-weighted precision value and an average recall value. A position-weighted precision can be calculated 602 for a suggested user interface action, e.g., by the 3D modeling program 116, following the process 400 described in FIG. 4A. An average recall can be calculated 604 for the suggested user interface action by averaging recalls calculated for two or more sub-windows of the window, e.g., by the 3D modeling program 116, following the process 500 described in FIG. 5A. A position-based F-measure (e.g., a position-based F-score) can be generated 606 for the suggested user interface action based on the position-weighted precision and the average recall, e.g., by the 3D modeling program 116. For example, the position-based F-score can be calculated using the formula:

$$\frac{2 * ( PositionWeightedPrecision * AverageRecall )}{( PositionWeightedPrecision + A v e r a g e R e c a l l )}$$

FIG. 7 is a flowchart showing an example of a process 700 to generate a summary associated with an insight. Text data associated with a current suggested user interface action, can be generated 702 by a generative language model and based on domain knowledge data, e.g., by the 3D modeling program 116. The generative language model can be a machine learning model trained to generate a generative output in natural language. For example, the generative language model can be an LLM. The text data can include a natural language summary associated with the current suggested user interface action, aiming at capturing important information from the domain knowledge data given the individual needs and context of the user. For example, the text data can provide guidance to perform the suggested user interface action and can include a summary of online documentation for the suggested user interface action.

Candidate questions can be generated 704 based on the text data, e.g., by the 3D modeling program 116. For example, the 3D modeling program 116 can generate candidate questions based on the natural language summary 126. In some implementations, the 3D modeling program 116 can generate the candidate questions through an instruction-based prompt. In some implementations, the 3D modeling program 116 can use a generative language model to process the text data and extract keywords for the text data, e.g., the top ten keywords. In some implementations, the 3D modeling program 116 can generate the candidate questions which are designed to be answerable with a single word from the text. For example, the 3D modeling program 116 can generate candidate questions using a question generation machine learning model trained to generate questions.

A mean and a standard deviation of respective scores for the candidate questions can be calculated 706, e.g., by the 3D modeling program 116. The score for each candidate question can include a weighted sum of a relevance score, a uniqueness score, a completeness score, an answerability score, a difficulty score, and a clarity score for the candidate question. In some implementations, the 3D modeling program 116 can rank the candidate questions based on the scores for the candidate questions.

For example, using the Average Modified Question Answering and Generation for Summarization (AmQAGS) method, the 3D modeling program 116 can determine a score for each candidate question based on a set of factors. The set of factors can include similarity to the text data (relevance), presence of keywords (uniqueness), grammatical correctness (completeness), complexity of the question (difficulty), presence of question words in the text data (answerability), absence of passive voice (clarity), readability, a domain-specific criteria, and other characteristics of the candidate questions. The score can be a weighted sum of two or more of the set of factors, such as a weighted sum of two or more of a relevance score, a uniqueness score, a completeness score, an answerability score, a difficulty score, a clarity score, a readability score, a domain-specific score (e.g., calculated based on the presence of the domain-specific terminology) for the candidate question. The weight for each factor can be a number that represents the importance of that factor.

For example, the 3D modeling program 116 can determine the relevance score by calculating term frequency-inverse document frequency (TF-IDF) vectors for the candidate questions and the text data and determining a cosine similarity of the TF-IDF vectors. The 3D modeling program 116 can determine the complexity score by counting the number of words in each question, the number of clauses in a question, or both. The 3D modeling program 116 can determine the uniqueness score based on the presence of keywords in the candidate questions. For example, for each candidate question, the 3D modeling program 116 can calculate the density of unique keywords in the candidate question by comparing to a reference set of keywords. The question with a higher density of unique keywords can receive a higher uniqueness score. The 3D modeling program 116 can determine the completeness score based on the presence of a noun and a verb in the candidate question. The 3D modeling program 116 can determine the answerability score based on the presence of words of the candidate question in the text data. The 3D modeling program 116 can determine the clarity score based on whether the candidate question is in an active voice. The 3D modeling program 116 can determine the readability score based on the Flesch Reading Ease score.

A subset of questions can be selected 708 from the candidate questions by comparing the respective scores for the questions to a threshold determined based on the mean and the standard deviation, e.g., by the 3D modeling program 116. This thresholding process may result in a varying number of subset of questions for different types of text data. For example, four questions can be selected from ten candidate questions.

For example, the 3D modeling program 116 can calculate a mean and a standard deviation of respective scores for the candidate questions. The mean of the scores can be an average of all the scores. The standard deviation can measure the dispersion or variation in the scores. The 3D modeling program 116 can determine a threshold based on the mean and the standard deviation and the threshold can be used to filter high-quality questions.

For example, the threshold can be a dynamic threshold that equals a sum of the mean and 0.5 times the standard deviation. The 3D modeling program 116 can select a subset of questions from the candidate questions by comparing the respective scores for the candidate questions to the threshold. For example, the 3D modeling program 116 can select questions that have scores larger than the threshold, indicating that the questions are more likely to be relevant, unique, complete, answerable, difficult, and clear. By using this question ranking and thresholding logic, the AmQAGS method can ensure that only high-quality and relevant questions are selected for the factual consistency analysis.

Whether to display the text data together with the current suggested user interface action can be determined 710 by comparing (a) first answers to the subset of questions generated based on domain knowledge data, and (b) second answers to the subset of questions generated based on the text data, e.g., by the 3D modeling program 116. For example, for each question in the subset of questions, the 3D modeling program 116 can instruct a large language model to generate one-word answers from both the summarized text data and the original text. The 3D modeling program 116 can determine a performance score for the text data (e.g., the summary) based on the comparison of the first and second answers. The 3D modeling program 116 can determine whether to display the text data based on the performance score.

In some implementations, the 3D modeling program 116 can determine the number of second answers that match the first answers, and the performance score for the text data can be the ratio of matching answers to the total number of the subset of questions. The ratio can indicate accuracy and truthfulness of the text data. The 3D modeling program 116 can determine whether to display the text data based on whether the ratio is larger than a threshold, e.g., 75%. In some implementations, the performance score for the text data can be based on both the number of matching answers to the total number of the subset of questions and the rankings of the subset of questions. For example, a question with a higher ranking can have more weight.

In response to determining to display the text data together with the current suggested user interface action, the text data is displayed 712 together with the current suggested user interface action. In response to determining not to display the text data together with the current suggested user interface action, the text data is not displayed together with the current suggested user interface action. In some implementations, the 3D modeling program 116 regenerates an updated text data associated with the current suggested user interface action using a different generative language model, or the same generative language model with one or more different parameters.

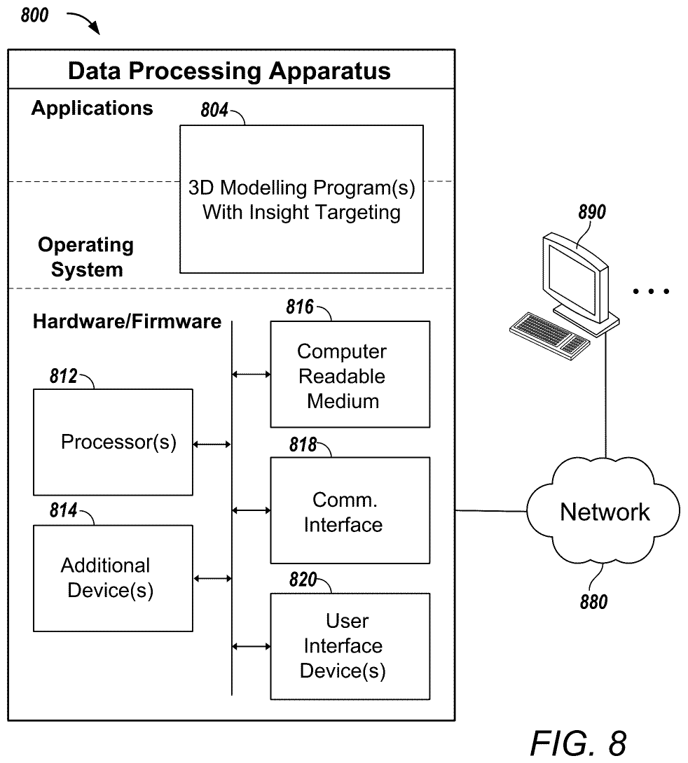

FIG. 8 is a schematic diagram of a data processing system including a data processing apparatus 800, which can be programmed as a client or as a server. The data processing apparatus 800 is connected with one or more computers 890 through a network 880. While only one computer is shown in FIG. 8 as the data processing apparatus 800, multiple computers can be used. The data processing apparatus 800 includes various software modules, which can be distributed between an application layer and an operating system. These can include executable and/or interpretable software programs or libraries, including tools and services of one or more 3D modeling program(s) 804 that implement the systems and techniques described herein. Thus, the 3D modeling program(s) 804 can be CAD program(s) that implements insight targeting in computer aided design and manufacturing. In some implementations, the executable and/or interpretable software programs or libraries can include tools and services of one or more 2D or 3D program(s) that implement the systems and techniques described herein. The one or more 2D or 3D program(s) can include design, modeling, graphic editing, and computer animation programs and applications. The number of software modules used can vary from one implementation to another. Moreover, the software modules can be distributed on one or more data processing apparatus connected by one or more computer networks or other suitable communication networks.

The data processing apparatus 800 also includes hardware or firmware devices including one or more processors 812, one or more additional devices 814, a computer readable medium 816, a communication interface 818, and one or more user interface devices 820. Each processor 812 is capable of processing instructions for execution within the data processing apparatus 800. In some implementations, the processor 812 is a single or multi-threaded processor. Each processor 812 is capable of processing instructions stored on the computer readable medium 816 or on a storage device such as one of the additional devices 814. The data processing apparatus 800 uses the communication interface 818 to communicate with one or more computers 890, for example, over the network 880. Examples of user interface devices 820 include a display, a camera, a speaker, a microphone, a tactile feedback device, a keyboard, a mouse, and VR and/or AR equipment. The data processing apparatus 800 can store instructions that implement operations associated with the program(s) described above, for example, on the computer readable medium 816 or one or more additional devices 814, for example, one or more of a hard disk device, an optical disk device, a tape device, and a solid state memory device.

Embodiments of the subject matter and the functional operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented using one or more modules of computer program instructions encoded on a non-transitory computer-readable medium for execution by, or to control the operation of, data processing apparatus. The computer-readable medium can be a manufactured product, such as a hard drive in a computer system or an optical disc sold through retail channels, or an embedded system. The computer-readable medium can be acquired separately and later encoded with the one or more modules of computer program instructions, e.g., after delivery of the one or more modules of computer program instructions over a wired or wireless network. The computer-readable medium can be a machine-readable storage device, a machine-readable storage substrate, a memory device, or a combination of one or more of them.

The term “data processing apparatus” encompasses all apparatus, devices, and machines for processing data, including by way of example a programmable processor, a computer, or multiple processors or computers. The apparatus can include, in addition to hardware, code that produces an execution environment for the computer program in question, e.g., code that constitutes processor firmware, a protocol stack, a database management system, an operating system, a runtime environment, or a combination of one or more of them. In addition, the apparatus can employ various different computing model infrastructures, such as web services, distributed computing and grid computing infrastructures.

A computer program (also known as a program, software, software application, script, or code) can be written in any suitable form of programming language, including compiled or interpreted languages, declarative or procedural languages, and it can be deployed in any suitable form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM (Erasable Programmable Read-Only Memory), EEPROM (Electrically Erasable Programmable Read-Only Memory), and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., an LCD (liquid crystal display) display device, an OLED (organic light emitting diode) display device, or another monitor, for displaying information to the user, and a keyboard and a pointing device, e.g., a mouse or a trackball, by which the user can provide input to the computer. Other kinds of devices can be used to provide for interaction with a user as well; for example, feedback provided to the user can be any suitable form of sensory feedback, e.g., visual feedback, auditory feedback, or tactile feedback; and input from the user can be received in any suitable form, including acoustic, speech, or tactile input.

The computing system can include clients and servers. A client and server are generally remote from each other and typically interact through a communication network. The relationship of client and server arises by virtue of computer programs running on the respective computers and having a client-server relationship to each other. Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a browser user interface through which a user can interact with an implementation of the subject matter described is this specification, or any combination of one or more such back-end, middleware, or front-end components. The components of the system can be interconnected by any suitable form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While this specification contains many implementation details, these should not be construed as limitations on the scope of what is being or may be claimed, but rather as descriptions of features specific to particular embodiments of the disclosed subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the invention have been described. Other embodiments are within the scope of the following claims. In addition, actions recited in the claims can be performed in a different order and still achieve desirable results.

What is claimed is:

1. A method comprising:
obtaining, by a three-dimensional modeling program, two or more suggested user interface actions, wherein each suggested user interface action of the two or more suggested user interface actions is proposed by an insight targeting model in response to a corresponding received user interface action with the three-dimensional modeling program;
generating, by the three-dimensional modeling program, a score for each suggested user interface action of the two or more suggested user interface actions, wherein the score is based on a position of the suggested user interface action being received within a window that comprises two or more user interface actions that are received after the corresponding received user interface action; and
producing, by the three-dimensional modeling program, a performance evaluation result of the insight targeting model based on the scores for the two or more suggested user interface actions.

2. The method of claim 1, further comprising:
receiving, by the three-dimensional modeling program, a current suggested user interface action that is proposed by the insight targeting model in response to a current received user interface action with the three-dimensional modeling program;
determining, by the three-dimensional modeling program, whether to display the current suggested user interface action on a user interface of the three-dimensional modeling program based on the performance evaluation result of the insight targeting model; and
in response to determining to display the current suggested user interface action, displaying, by the three-dimensional modeling program, the current suggested user interface action on the user interface of the three-dimensional modeling program.

3. The method of claim 2, further comprising:
generating, by a generative language model and based on domain knowledge data, text data associated with the current suggested user interface action;
generating candidate questions based on the text data;
calculating a mean and a standard deviation of respective scores for the candidate questions, wherein the score for each candidate question comprises a weighted sum of a relevance score, a uniqueness score, a completeness score, an answerability score, a difficulty score, and a clarity score for the candidate question;
selecting a subset of questions from the candidate questions by comparing the respective scores for the questions to a threshold determined based on the mean and the standard deviation; and
determining whether to display the text data together with the current suggested user interface action by comparing (a) first answers to the subset of questions generated based on domain knowledge data, and (b) second answers to the subset of questions generated based on the text data.

4. The method of claim 1, wherein generating the score for each suggested user interface action comprises:
calculating a precision for the suggested user interface action, wherein the precision is a likelihood that the suggested user interface action is performed by a user within the window;
calculating a positional decay weight using the position of the suggested user interface action being received within the window, wherein the positional decay weight is higher at a beginning of the window, in which the suggested user interface action occurs, than at an ending of the window; and
calculating the score by multiplying the precision and the positional decay weight.

5. The method of claim 1, wherein generating the score for each suggested user interface action comprises:
determining two or more sub-windows of the window, wherein each sub-window of the two or more sub-windows includes a different subset of user interface actions from the two or more user interface actions that are received after the received user interface action;
for each sub-window of the two or more sub-windows, determining a recall of the suggested user interface action within the sub-window, wherein the recall is a likelihood that the subset of user interface actions in the sub-window correspond to the suggested user interface action; and
calculating the score by averaging the recalls for the two or more sub-windows.

6. The method of claim 5, wherein a size of the window is N, which is at least two, the two or more user interface actions within the window are at positions from 1 through N, determining the two or more sub-windows of the window comprises:
determining N sub-windows of the window, wherein each sub-window has a window length of n, and includes user interface actions at positions 1 through n of the window, n is between 1 and N.

7. The method of claim 1, wherein generating the score for each suggested user interface action comprises:
calculating a precision for the suggested user interface action, wherein the precision is a likelihood that the suggested user interface action is performed by a user within the window;
calculating a positional decay weight using the position of the suggested user interface action being received within the window, wherein the positional decay weight is higher at a beginning of the window, in which the suggested user interface action occurs, than at an ending of the window;
calculating a first score by multiplying the precision and the positional decay weight;
determining two or more sub-windows of the window, wherein each sub-window of the two or more sub-windows includes a different subset of user interface actions from the two or more user interface actions that are received after the received user interface action;
for each sub-window of the two or more sub-windows, determining a recall of the suggested user interface action within the sub-window, wherein the recall is a likelihood that the subset of user interface actions in the sub-window correspond to the suggested user interface action;
calculating a second score by averaging the recalls for the two or more sub-windows; and
generating the score based on the first score and the second score.

8. The method of claim 1, wherein the performance evaluation result comprises an average of the scores for the two or more suggested user interface actions.

9. The method of claim 1, comprising:
displaying, to a user and on a user interface of the three-dimensional modeling program, each suggested user interface action of the two or more suggested user interface actions after receiving the corresponding user interface action; and
after displaying each suggested user interface action of the two or more suggested user interface actions to the user, receiving the two or more user interface actions performed by the user within the window.

10. A system comprising:
a non-transitory storage medium having instructions of a three-dimensional modeling program stored thereon; and
one or more data processing apparatus configured to run the instructions of the three-dimensional modeling program to perform operations specified by the instructions of the three-dimensional modeling program;
wherein the operations comprise:
obtaining, by the three-dimensional modeling program, two or more suggested user interface actions, wherein each suggested user interface action of the two or more suggested user interface actions is proposed by an insight targeting model in response to a corresponding received user interface action with the three-dimensional modeling program;
generating, by the three-dimensional modeling program, a score for each suggested user interface action of the two or more suggested user interface actions, wherein the score is based on a position of the suggested user interface action being received within a window that comprises two or more user interface actions that are received after the corresponding received user interface action; and
producing, by the three-dimensional modeling program, a performance evaluation result of the insight targeting model based on the scores for the two or more suggested user interface actions.

11. The system of claim 10, wherein the operations further comprise:
receiving, by the three-dimensional modeling program, a current suggested user interface action that is proposed by the insight targeting model in response to a current received user interface action with the three-dimensional modeling program;
determining, by the three-dimensional modeling program, whether to display the current suggested user interface action on a user interface of the three-dimensional modeling program based on the performance evaluation result of the insight targeting model; and
in response to determining to display the current suggested user interface action, displaying, by the three-dimensional modeling program, the current suggested user interface action on the user interface of the three-dimensional modeling program.

12. The system of claim 11, wherein the operations further comprise:
generating, by a generative language model and based on domain knowledge data, text data associated with the current suggested user interface action;
generating candidate questions based on the text data;
calculating a mean and a standard deviation of respective scores for the candidate questions, wherein the score for each candidate question comprises a weighted sum of a relevance score, a uniqueness score, a completeness score, an answerability score, a difficulty score, and a clarity score for the candidate question;
selecting a subset of questions from the candidate questions by comparing the respective scores for the questions to a threshold determined based on the mean and the standard deviation; and
determining whether to display the text data together with the current suggested user interface action by comparing (a) first answers to the subset of questions generated based on domain knowledge data, and (b) second answers to the subset of questions generated based on the text data.

13. The system of claim 10, wherein generating the score for each suggested user interface action comprises:
calculating a precision for the suggested user interface action, wherein the precision is a likelihood that the suggested user interface action is performed by a user within the window;
calculating a positional decay weight using the position of the suggested user interface action being received within the window, wherein the positional decay weight is higher at a beginning of the window, in which the suggested user interface action occurs, than at an ending of the window; and
calculating the score by multiplying the precision and the positional decay weight.

14. The system of claim 10, wherein generating the score for each suggested user interface action comprises:
determining two or more sub-windows of the window, wherein each sub-window of the two or more sub-windows includes a different subset of user interface actions from the two or more user interface actions that are received after the received user interface action;
for each sub-window of the two or more sub-windows, determining a recall of the suggested user interface action within the sub-window, wherein the recall is a likelihood that the subset of user interface actions in the sub-window correspond to the suggested user interface action; and
calculating the score by averaging the recalls for the two or more sub-windows.

15. The system of claim 14, wherein a size of the window is N, which is at least two, the two or more user interface actions within the window are at positions from 1 through N, determining the two or more sub-windows of the window comprises:
determining N sub-windows of the window, wherein each sub-window has a window length of n, and includes user interface actions at positions 1 through n of the window, n is between 1 and N.

16. The system of claim 10, wherein generating the score for each suggested user interface action comprises:
calculating a precision for the suggested user interface action, wherein the precision is a likelihood that the suggested user interface action is performed by a user within the window;
calculating a positional decay weight using the position of the suggested user interface action being received within the window, wherein the positional decay weight is higher at a beginning of the window, in which the suggested user interface action occurs, than at an ending of the window;
calculating a first score by multiplying the precision and the positional decay weight;
determining two or more sub-windows of the window, wherein each sub-window of the two or more sub-windows includes a different subset of user interface actions from the two or more user interface actions that are received after the received user interface action;
for each sub-window of the two or more sub-windows, determining a recall of the suggested user interface action within the sub-window, wherein the recall is a likelihood that the subset of user interface actions in the sub-window correspond to the suggested user interface action;
calculating a second score by averaging the recalls for the two or more sub-windows; and
generating the score based on the first score and the second score.

17. The system of claim 10, wherein the performance evaluation result comprises an average of the scores for the two or more suggested user interface actions.

18. The system of claim 10, wherein the operations comprise:
displaying, to a user and on a user interface of the three-dimensional modeling program, each suggested user interface action of the two or more suggested user interface actions after receiving the corresponding user interface action; and
after displaying each suggested user interface action of the two or more suggested user interface actions to the user, receiving the two or more user interface actions performed by the user within the window.

19. A non-transitory computer-readable medium encoding instructions operable to cause data processing apparatus to perform operations comprising:
obtaining, by a three-dimensional modeling program, two or more suggested user interface actions, wherein each suggested user interface action of the two or more suggested user interface actions is proposed by an insight targeting model in response to a corresponding received user interface action with the three-dimensional modeling program;
generating, by the three-dimensional modeling program, a score for each suggested user interface action of the two or more suggested user interface actions, wherein the score is based on a position of the suggested user interface action being received within a window that comprises two or more user interface actions that are received after the corresponding received user interface action; and
producing, by the three-dimensional modeling program, a performance evaluation result of the insight targeting model based on the scores for the two or more suggested user interface actions.

20. The non-transitory computer-readable medium of claim 19, wherein the operations further comprise:
receiving, by the three-dimensional modeling program, a current suggested user interface action that is proposed by the insight targeting model in response to a current received user interface action with the three-dimensional modeling program;
determining, by the three-dimensional modeling program, whether to display the current suggested user interface action on a user interface of the three-dimensional modeling program based on the performance evaluation result of the insight targeting model; and
in response to determining to display the current suggested user interface action, displaying, by the three-dimensional modeling program, the current suggested user interface action on the user interface of the three-dimensional modeling program.
